(19) United States
(12) Patent Application Publication
(10) Pub. No.: US 2026/0130130 A1
(43) Pub. Date: May 7, 2026

(54) SILICON WAFERS WITH THINNED SECTIONS TO THERMALLY ISOLATE DENSELY WIRED QUBITS

(71) Applicant: Qolab, Inc., Los Angeles, CA (US)

(72) Inventors: John Matthew Martinis, Santa Barbara, CA (US); Robert Francis McDermott, III, Madison, WI (US); Alan Kar-Lun Ho, Los Angeles, CA (US)

(21) Appl. No.: 18/906,072

(22) Filed: Oct. 3, 2024

(51) Int. Cl. H10N 69/00; G06N 10/40; H10N 60/80; H10N 60/82; H10N 60/85

(52) U.S. Cl. CPC H10N 69/00; G06N 10/40; H10N 60/805; H10N 60/82; H10N 60/85

(57) ABSTRACT

A quantum computing system with structures for wiring superconducting qubits between varying thermal regimes is presented. This system enables the control of many thousands to millions of qubits operated at typical qubit operating temperatures, while the control electronics operate at much higher temperatures, such as 3-4 K, 50-77 K, or 300 K. The system includes a qubit substrate with one or more qubits, a metallization layer, a wiring substrate comprising superconducting striplines, a mechanical mount, and a quantum computing device. The system includes structures disposed throughout that connect a lower temperature section for qubit operation to a higher temperature section for control operations. The system also employs flex circuit boards for achieving dense and scalable connectivity. Methods for fabricating the quantum computing system are also disclosed.

### BACKGROUND

### Field of Disclosure

This invention relates generally to quantum computing, and more particularly to the wiring of superconducting qubits to higher-temperature control circuitry using silicon wafers.

### Description of Related Art

Quantum computers perform calculations that cannot be run by classical supercomputers, such as efficient prime factorization or solving how molecules bind using quantum chemistry. The most difficult problems can only be solved by embedding the algorithm in a large quantum computer that is running quantum error correction. However, this requires the control of many thousands to millions of qubits, and the power budget for such a system typically constrains the control signals to be generated by electronics that are at a much higher temperature than the qubits themselves. For example, the qubits are typically operated at about 20 mK, whereas the control electronics can be at temperature stages of 3-4 K, 50-77 K or 300 K.

In turn, wiring must be used to connect the qubits operating at low temperatures to control electronics operating at higher temperatures. Although coaxial wiring has been used successfully in the past few decades, this solution is not expected to be scalable to the many thousands to millions of wires that will be needed for a large quantum computer. A solution is needed that both retains the electrical integrity of the signals, but can be densely packed, fabricated and assembled at reasonable cost.

To illustrate this difficulty, the permissible thermal load at the qubit temperature is low, less than 1 mW, whereas at higher temperatures the thermal load is significantly higher, roughly 20 W at 3-4 K, 1 kW at 77 K, and greater than 10 kW at 300 K. Due to the different thermal and electrical physics over this large temperature range, different wiring solutions from 20 mK to 3 K, and then from 3 K and higher are worthwhile.

### SUMMARY

The systems and method herein describe a wiring solution from 20 mK to 3-4 K (and possibly from 3-4 K and higher) using superconducting wiring. The wiring is fabricated using photolithographic technology on large 300 mm Silicon wafers. Superconductivity allows the use of transmission-line wiring with small dimensions without introducing electrical damping and waveform distortion of the control signals. Small dimensions in this case indicate sizes on the order of 1 micrometer (um), such as, e.g., 20 nanometers (nm), 50 nm, 100 nm, 250 nm, 500 nm, 1 um, 5 um, 10 um, etc. Dense writing can be fabricated using traditional integrated circuit technology. Even though there may be many thousands of wires, the low thermal conductance of superconductors gives low heat loads to low temperature, providing thermal isolation.

Notably, however, the additional, strong thermal conductivity comes from the Silicon wafer, which is much thicker (e.g., 775 um) than the superconducting wiring layer (e.g., 1 um). To reduce the thermal conductivity, one or more portions of the Silicon wafer are processed (e.g., micromachined, lithography processes, etc.) to reduce its thickness to about 0.1-50 um using an etching process, where the thinned sections (e.g., windows) are lithographically defined. By using thermal anchoring at intermediate temperature stages of 1 K or below, the resulting heat load to the qubits at 20 mK can be made acceptably low. In other words, the silicon wafer is fabricated to create a series of thermally isolated sections that reduce the thermal load of wires connecting higher temperatures to lower temperatures.

Additionally, the transmission-line wiring typically employs filtering of electrical signals above about 1 GHz to reduce thermal noise coming from higher temperatures, which would produce errors in the qubits. To this end, a compact transmission-line filter that is compatible with the dense wiring for the disclosed wiring solution is also described. The wires can be brought out to pads at 3-4 K to connect to electronics at this stage, as well as to wiring to higher temperatures.

Because there are no easily fabricated superconductors at temperatures above 3-4 K, flex wiring is fabricated using a Copper alloy fabricated in a conventional means using well understood fabrication techniques. The flex wiring can be connected to the Silicon substrate at 3-4 K using conventional spring connectors, since the small resistance of the connector (1-10 mOhms) produces only a small heat load at 3-4 K. Such power loss at the qubit temperature is detrimental to device function, and thus the Silicon wiring provides a method to readily connect to the qubits without thermal loading.

The fabrication technology of this Silicon wiring is generally different than needed for the superconducting qubits. As such, a dense array of bump bonds, made from superconducting indium, are fabricated to connect qubits from a qubit wafer (e.g., made from 200 millimeter (mm) or 300 mm processes) to the a wiring wafer (e.g., made from 200 mm or 300 mm processes). Thus, wires for about 20k qubits can be connected with a single-step bump bonding operation.

Finally, these wafers can be tiled together in a modular manner for a greater qubit count, to the millions or more.

### BRIEF DESCRIPTION OF THE DRAWINGS

FIG. 1 shows a cross-section view of the quantum computer system, in accordance with an example embodiment.

FIG. 2 shows a cross-section of the quantum computing system, in accordance with an example embodiment.

FIG. 3 shows a schematic layout of the wiring between the qubit substrate and the wiring substrate for a qubit cell, in accordance with an example embodiment.

FIG. 4 shows a cross-sectional view of the wiring substrate fabricated on a Silicon wafer, in accordance with an example embodiment.

FIG. 5 shows a cross-sectional view of the thermal-isolation section of the wiring substrate, in accordance with an example embodiment.

FIG. 6 shows an isometric drawing of the microstrip flex circuit at the edge connection, in accordance with an example embodiment.

FIG. 7 shows an example tiling between two modules, in accordance with an example embodiment.

FIG. 8 shows three examples for tiling the modules, in accordance with an example embodiment.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

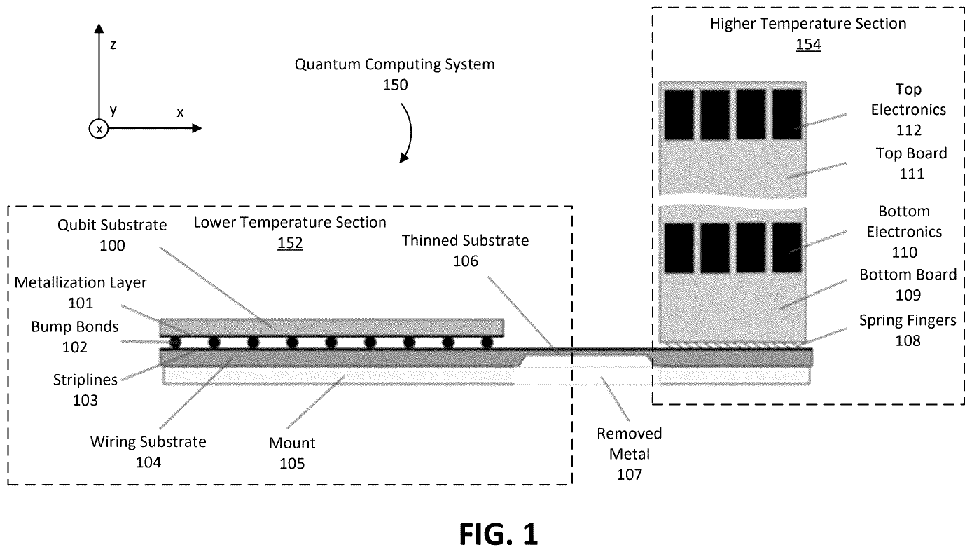

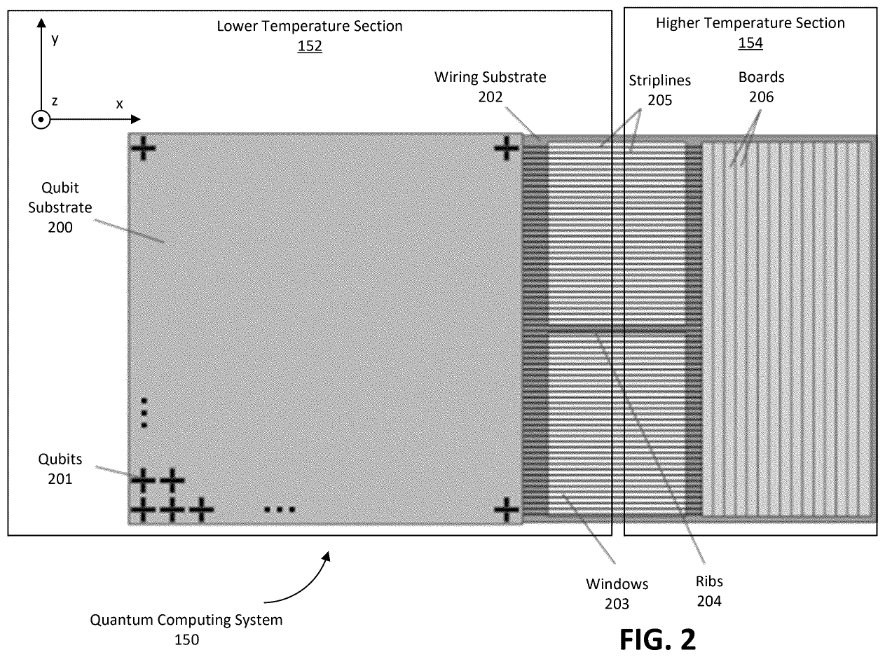

As described above, a quantum computing system with structures for wiring superconducting qubits between varying thermal regimes are disclosed herein, as well as the methods for fabricating those structures. FIGS. 1 and 2 illustrate such a structure. More specifically, FIG. 1, shows a cross-section view of the quantum computer system from a first viewpoint, in accordance with an example embodiment. FIG. 2, shows a cross-section view of the quantum computer system from a second viewpoint, according to an example embodiment.

More contextually, FIG. 1 shows a cross-section view of the device from a first plane, and FIG. 2 shows a cross section of the device view from a second plane orthogonal to the first plane, as illustrated. More specifically, FIG. 1 illustrates the quantum computing system along the x-z plane looking in the y direction, and FIG. 2 illustrates the quantum computing system along the x-y plane looking in the-z direction.

As illustrated in FIG. 1, the quantum computing system 150 has a qubit substrate 100. The qubit substrate 100 comprises one or more qubits. The qubits may be, e.g., a superconducting qubit comprising a Josephson junction. The qubit substrate 100 has the qubit metallization layer 101 at the bottom of the substrate. The metallization layer 101 is bump-bonded 102 to the wiring substrate 104. The wiring substrate 104 includes superconducting striplines 103 on the top surface. The wiring substrate 104 is thermally and mechanically connected to a mechanical mount 105 for robust handling.

The quantum computing system 150 shows a lower temperature section 152 (left side) and a higher temperature section 154 (right side). The lower temperature section 152 surrounding the qubit substrate 100 operates in a lower temperature environment (e.g., is connected to low temperatures such as 20 mK), whereas the higher temperature section operates in a higher temperature environment (e.g., is connected to the higher temperatures 3-4 K). Thermal power from the higher temperature section (e.g., 3-4 K) to the lower temperature section (e.g., 20 mK) is reduced by thinning the wiring substrate (e.g., thinned substrate 106) and removing metal from the mount (removed metal 107). In some cases, the thinning and removing of wiring substrate material creates windows.

In the higher temperature section 154, spring fingers 108 (or some other electrical contact) connect the electrical signals from pads on the wiring substrate to the bottom edge of the flex circuit board 109 and 111. In the higher temperature section 152, the bottom flex circuit board 109 is separated by 5 cm to 100 cm from the top flex circuit board 111. There can be a temperature gradient across the flex circuit boards 109, 111 that allows different electronics 110, 112 to be mounted at different temperatures. For example, electronic devices 110 can be mounted on this flex circuit board near the bottom 109 at, e.g., 3-4K, or electronic devices 112 can be mounted on the flex circuit board near the top 111 at higher temperatures 112 (e.g., 270 K).

The quantum computing device 150 is also illustrated in FIG. 2. As shown in FIG. 2, the qubit substrate 200 (e.g., qubit substrate 100) contains an array of qubits 201. The qubit substrate 200 lies on top of the wiring substrate 202 (e.g., wiring substrate 104). The substrate 202 (e.g., substrate 106) and/or mount (e.g., mount 107, not shown) are etched to create thinned sections (e.g., windows 203). In some cases, as illustrated, the windows include ribs 204. The ribs 204 include portions of the wiring substrate 202 that is not wholly removed or is thinned to a lesser degree. The ribs 204 increase mechanical rigidity of the quantum computing device 150.

Wiring from left to right includes a plurality of stripline transmission lines 205 (e.g., striplines 103). The striplines 205 connect qubits 201 of the qubit substrate 200 in the lower temperature section 152 to the higher temperature section 154. For instance, the striplines connect the qubit chip at 20 mK to flex wiring and flex circuit boards 206 (e.g., flex circuit board 109) at 3-4K. A plurality of flex circuit boards 206 may be stacked for dense connectivity.

Fabricating the quantum computing system 150 illustrated in FIGS. 1 and 2 and described herein is non-trivial.

To create this structure, referring to FIG. 2, the qubits are fabricated on a qubit substrate 200. The qubit substrate 200 can be Silicon or Sapphire but may be another material. The qubit substrate 200 may have a diameter of 200 mm but could have other diameters. Fabrication of qubits on the qubit substrate 200 uses standard microelectronics technology, including optical and/or electron beam lithography, thin film deposition, liftoff, etching, etc.

The qubit substrate 200 may be cut into a square in order to tile wafers together and to give more space for the wiring substrate 104, as discussed hereinbelow (as shown in FIG. 2). A 200 mm wafer, for example, may be cut into 140 mm by 140 mm sections. An array of qubits 201 is fabricated on the qubit substrate 200, with a typical pitch of 100 um to 3 mm, depending on the design. For the example of a 1 mm pitch, 140*140=19600 qubits would fit on the wafer.

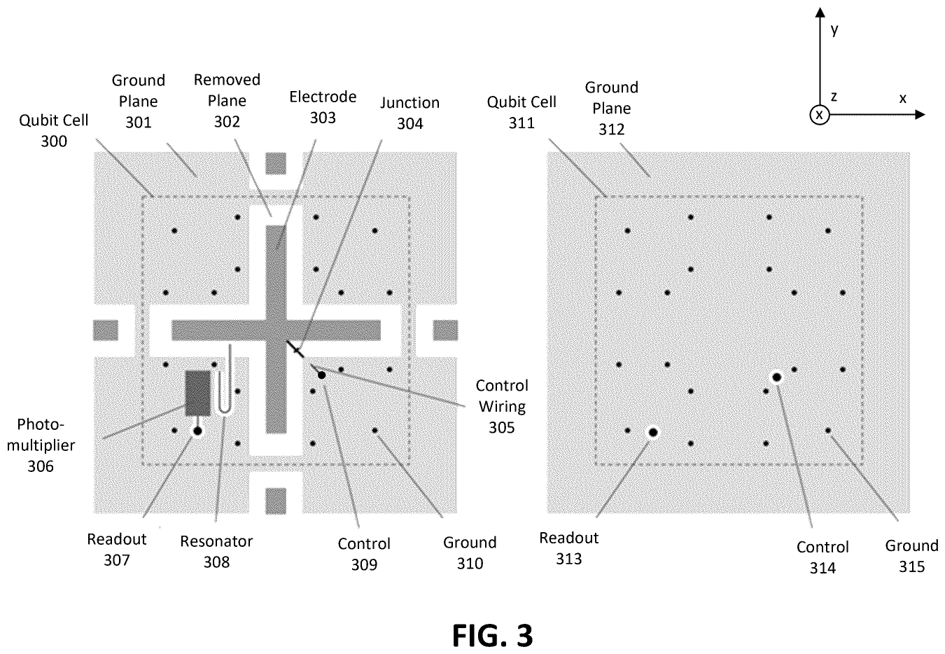

The system 150 is fabricated such that each qubit 201 is connected to wiring (e.g., striplines 205) to control and measure the qubit. Because the qubits are fabricated with low-loss materials and interfaces, the system 150 employs an easily produceable wiring geometry such as coplanar waveguides. The geometry allows qubit wiring to be short and located locally around the qubit Josephson junction (as shown in FIG. 3). The control signals are coupled to the qubits using bump bonds that connect the qubit to a wiring substrate 202. The wiring substrate 202 is fabricated using a process that allows well-shielded and dense “escape wiring” (e.g., striplines 205) from the qubit to the edge of the wafer. The bump bonds are fabricated with a superconducting material, such as Indium or solder bumps.

The qubits are fabricated on the qubit substrate 200 such that the surface of the substrate 200 including the qubits 201 faces the surface the wiring substrate 202. The bump bonds (e.g., bump bonds 102) connect to the two surfaces. In some configurations, the system 150 may include qubits 201 and wiring on both sides of the qubit substrate 200, connected with through-hole vias, and for the qubit array to include a stack of bump bonded wafers. In addition to connecting control lines between the qubit 200 and wiring substrate 202, these bump bonds are also used to connect the ground planes of two chips (e.g., chips 310 and 315, as shown below) at many points to reduce microwave radiation and crosstalk. Bump bonds are described in greater detail in regard to FIG. 3 below.

The wiring substrate 202 is fabricated with electrical conductors made from a superconductor with a critical temperature greater than 3-4 K. As an example, the conductors may be Niobium, which is a common material for fabricating superconducting devices, but could be another material. Fabrication uses standard microelectronics technology, including optical and/or electron beam lithography, thin film deposition, liftoff, or chemical or gas-phase etching.

Like the qubit substrate 200, the wiring substrate 202 can be made from a 300 mm Silicon wafer so that it can be cut into a rectangle with width 140 mm (matching the qubit substrate 200). The length of the wiring substrate 202 may also be 260 mm (longer than the qubit substrate 200) so that there is room for wiring and connections to higher temperature, as shown in FIG. 2.

The description now turns to more in-depth descriptions of various aspects of the quantum computing system 150.

FIG. 3. shows a schematic layout of the wiring between the qubit substrate and a wiring substrate for a qubit cell, in accordance with an example embodiment. In the illustrated example, there is a qubit 300 cell outlined on the qubit substrate (e.g., qubit substrate 101) and qubit cell 311 outlined on the wiring substrate (e.g., wiring substrate 104). To aid in visualization, in this example, the qubit cell markers 300 and 311 are aligned in the quantum computing system 150. That is, the top left of the qubit cell 310 on the qubit substrate (left side) is aligned with, and vertically displaced in the z direction from, the top left of the qubit cell 311 on the wiring substrate. Each of the various bump bonds (indicated by dots) are approximately aligned between cells 300 and 311 and may electrically couple the qubit on the qubit substrate to the wiring substrate.

As illustrated, the qubit electrode 303 is formed with a Josephson junction 304. The qubit electrode 303 is fabricated by removing portions of the ground plane 301 (e.g., removed ground plane 302). The qubit control wiring 305 is a coplanar transmission line that connects to a bump bond (e.g., control 309). A readout resonator 308 is connected to a Josephson photomultiplier 306 (indicated by a darker area) and then to a bump bond (e.g., readout 307). A plurality of grounds (e.g., ground 310) are used to reduce microwave radiation. The surface of the wiring chip is mostly a ground plane 312, except for the readout 313 and control 314 bump bonds, along with a plurality of ground bump bonds 315. Notably, the array of illustrated bump bonds (e.g., 307, 309, 310, 313, 314, 315) may be differently configured to what is illustrated.

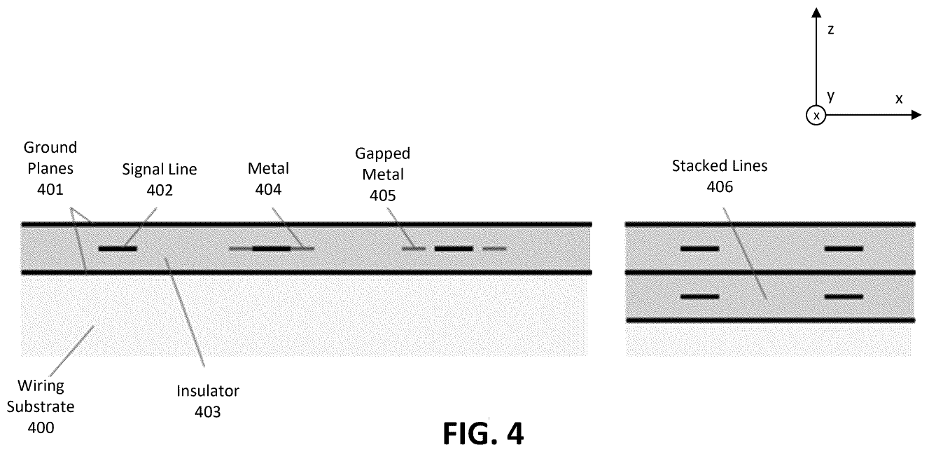

To continue, FIG. 4 shows a cross-sectional view of the wiring substrate, according to an example embodiment. The wiring substrate 400 (e.g., wiring substrate 104) is fabricated on, e.g., a silicon wafer, but could be fabricated on a different material. The microstrip transmission line consists of top and bottom ground planes 401 and a center signal line 402 made from a superconductor. The ground planes 401 and the signal line 402 and separated and electrically isolated from one another by an insulator 403. A stripline can be made to act as a low pass filter using metal (e.g., copper metal, illustrated as “metal 404”) connected to the signal line 404, or separated by a small gap 405 (e.g., gapped metal 405). In some configurations, the wiring density of the striplines can be increased with stacking (e.g., stacked lines 406).

Again, FIG. 4 shows example of the wiring geometry on the wiring substrate 400 with a stripline transmission line 402, which has ground shields 401 above and below the signal line to reduce crosstalk. To obtain a 50 ohm transmission line impedance, the typical dimensions of the line would be 0.1 to 0.5 um, with a pitch between signal lines of about 1 um. For the example of 2 um pitch, 70000 signal lines can be placed across the width of the 140 mm wafer, enough to control and readout all of the qubits. In other examples, depending on the pitch and the size of the striplines, the quantum computing system 150 could include between, e.g., 1,000 and 1,000,000 signal lines.

In an example configuration, the ground planes and the signal wires are separated by an insulator of 0.02 to 1 um in thickness, with typical thickness about 0.2 um. The insulator may be fabricated from, e.g., Silicon Dioxide or Silicon Nitride using standard deposition and etching techniques. A typical width of the wiring electrode is between, e.g., 50 nm and 5 um, but could be narrower or wider. In configurations where more striplines are needed, multiple layers of the stripline transmission lines could be fabricated 406.

The striplines connect the qubit controls at lower temperatures (e.g., 20 mK) to e.g., control electronics and/or additional wiring connections at higher temperatures (e.g., 3-4 K). Here, for example, a grid of contacts (e.g., spring fingers 108) with size 50 um to 2 mm may be employed to connect to CMOS or superconducting control and measurement electronics (e.g., bottom electronics 110) to additional wiring systems such as a flex board (e.g., top flex board 111) that are routed to even higher temperatures.

In some configurations, bump bonds (e.g., bump bonds 102) are used to connect control devices to the wiring substrate at 3-4 K. In additional examples, spring connectors (e.g., spring connectors 108) connect control devices to the wiring substrate, even though they typically have contact resistances in the 1-10 mOhm range and dissipate heat. The heat dissipated by spring connectors generally renders them unacceptable for thousands of connections at the qubit temperature of 20 mK, since the cooling power at 20 mK is typically less than 1 mW (which is why bump bonds are employed at lower temperatures). However, such power dissipation is acceptable at 3-4K (which is why spring connectors are employed to connect to the boards and electronics at higher temperatures). Indeed, spring connectors allow easy connection at 3-4 K, enabling the qubit and wiring substrate to be a modular sub-system. That is, the qubit and wiring substrate can be connected and disconnected easily, allowing for testing and scaling up to many modules.

Microwave noise and thermal radiation can transmit from 3-4 K to the qubits at 20 mK and cause detrimental qubit errors. With the coaxial wiring currently used, attenuators and low-pass filters are introduced into systems to isolate qubits from this noise. To remedy this issue in current technologies, FIG. 4 illustrates a thin-film solution for these filters. In the illustrated example, a metal (such as, e.g., Copper) is placed in contact with the signal layer 404 of the stripline, or in close proximity as in 405, so that the electromagnetic fields inside the transmission lines penetrate into this dissipative metal and attenuate the signal. The length of the metal in these transmission-line filters is chosen so the frequency crossover of the low-pass filter is 0.1 to 10 GHz, depending on the function of the control line. With the filter placed at the 20 mK section of the wiring substrate, thermal noise generated from the filter is small and is not detrimental to qubit performance.

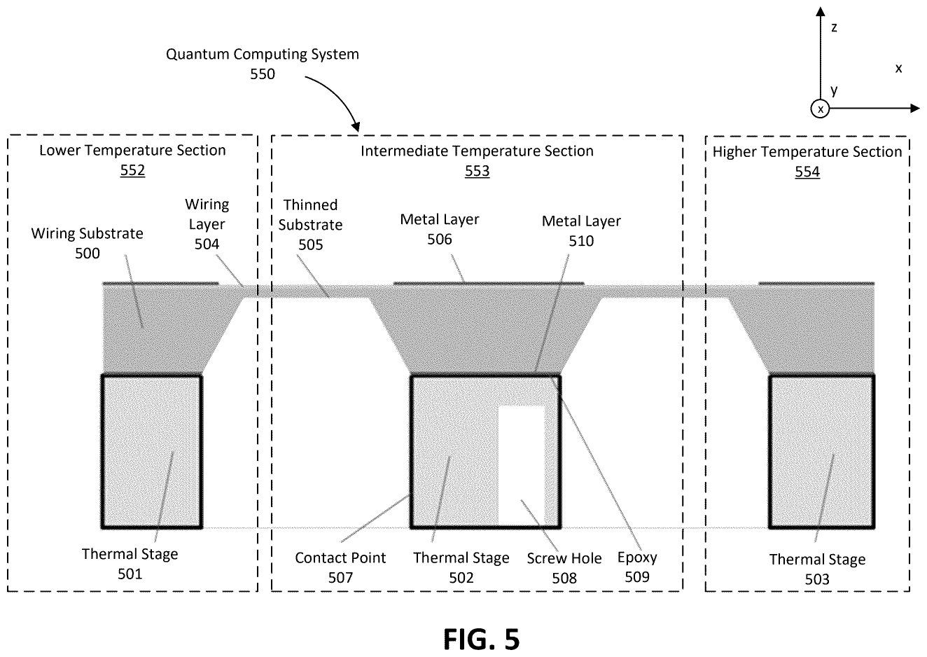

To continue, FIG. 5 shows a cross-sectional view of a thermal-isolation section of the wiring substrate, in accordance with an example embodiment. Notably, in this illustration, the quantum computing system 550 (e.g., quantum computing system 150) includes a wiring substrate 500 with several sections. As shown, the quantum computing system includes a lower temperature section 552 (e.g., 20 mK), an intermediate temperature section 553, and a higher temperature section 554 (e.g., 3-4 K). Each section is connected to the wafer mount at the lower temperature 501, the intermediate temperature 502, and the higher temperature 503. More intermediate layers are possible.

As illustrated, the superconducting wiring layer 504 (e.g., striplines 103) has a metal overlay 506 (e.g., Copper) at each of the 3 temperatures. The metal overlay 506 enables phonon thermalization within each section. The bottom of the wiring substrate can have a metal plating 510 (e.g., copper) to enhance the thermal connection 509 to the chip mount 501, 502 and 503. The chip mount is plated 507 with normal metal to enhance its thermal conductivity from the wiring wafer to thermal grounding screw in the mount 508.

Overall, the staged temperature sections (e.g., 552, 553, 554) enable thermal conductivity of the wiring substrate that allows heat to flow from the higher temperature section 554 (e.g., 3-4 K) to the lower temperature section 552 (e.g., 20 mK). Because superconductors have very low thermal conductivity at a temperature 5-10 times below the critical temperature and because the wiring is made from thin films, the thermal conductivity of the wiring itself is negligible. Thus, a large portion of the thermal conductivity in the system 550 comes from the Silicon wafer (e.g., wiring substrate 500). Even though Silicon is an insulator at low temperatures, the crystalline nature of the substrate implies that phonons that carry the heat will not scatter greatly, and thus produce significant thermal conductivity for a nominal thickness of 500-1000 um. In turn, to allow for thermal staging and isolation, the substrate is thinned between the various temperature stages (e.g., thinned substrate 505).

Depending on the degree of thermal isolation, the substrate is etched to create thin sections which have a remaining Silicon thickness from 0.1-50 um. The silicon is typically etched from the backside of the substrate wafer using standard micromachining techniques through a window etch-mask. The etching process can also be chosen so that the surface of the thinned substrate 505 has a roughness from 10 nm to 10 um to diffusively scatter the phonons reflecting from its surface to reduce their thermal conductivity. In another example, (as illustrated in FIG. 2) the thinned substrate 505 can retain unetched ribs (e.g., ribs 204) of the Silicon substrate to increase mechanical rigidity. The typical width of the ribs is 50 um to 2 mm but can be other widths.

Different numbers of intermediate temperature stages are possible. For instance, the system 550 may include intermediate temperature sections at 1 K, 0.6 K, and/or 0.1 K, etc. The intermediate heat stages are used to intercept the heat flow with thinned Silicon sections between the stages as related above. To thermalize the phonon heat at these stages (and at the lower temperature section 552), one or more metal layers (e.g., metal 506, 510) can be deposited and patterned at these stages. The metal layers may be Copper or some other metal. The thickness of the Copper is 0.1um to 10 um but other thicknesses are possible. Thermal phonons scatter with the electrons in the metal, downconverting the phonon energy and depositing their heat in the metal. Since the thermal heat capacity of a metal is much greater than the insulating substrate and has high thermal conductivity, the heat in the metal can be connected to the thermal stage 501, 502 and 503 and removed from the wiring substrate, for example by mechanical connection or through a thin layer of thermal grease or epoxy 509 to the substrate holder (e.g., mount 105), or with metal to metal contact between contact points (e.g., metal layer 510 to contact point 507), described below.

In effect, each of the intermediate stages (e.g., intermediate section 553) includes components that act as a heat sink for the temperature at that stage. To illustrate, contextually, a wiring line that travels from a higher temperature section (e.g., higher temperature section 554) to an intermediate temperature section (e.g., intermediate temperature section 553) generally carries a thermal load that is detrimental to qubit processing on a qubit substrate. The intermediate section is fabricated with a structure (e.g., substrate 500 and thinned substrate 505) and additional components (e.g., metal 506, thermal stage 502, etc.) that promote dissipation and removal of the heat carried into that section by the wiring line. This process can be repeated between sections until the thermal load carried by the wiring line is suitable for qubits on the qubit substrate.

The thinning of the Silicon can make the wiring substrate fragile when handling, reducing its effectiveness as a modular subsystem. Thus, the substrate(s) should be mounted on a mechanically strong frame (e.g., mount 105). Given the size of the substrate, the frame should be made with a similar coefficient of thermal contraction as that of Silicon (e.g., Invar). As this frame can also be used as a thermal connection, a good thermal conductor (e.g., Copper) can be plated (plated metal 507) onto the substrate at the various thermal stages. Thermal connections can be made through screw hole 508.

Additionally, interfacing with qubits on a qubit substrate at low temperatures is an important consideration for the quantum computing system 150. For instance, resonators with damping can be used to reset the qubits from higher energy levels. A typical circuit to implement this effect includes capacitively coupling the reset resonator to a frequency tunable qubit and turning on the damping by lowering the qubit frequency to the resonator frequency. These resonators can be placed on the qubit or interface substrate. The damping element can come from a normal metal film.

To continue, additional elements for the quantum computing system include devices and structures configured for the measurement of qubits.

For example, current technology uses several large (several cm³ in size) microwave circulators and parametric amplifiers at 20 mK, and relatively large (cm³) and high-power (10's of mW) HEMT amplifiers at 3-4 K. This solution is bulky, costly and seemingly impractical for measuring many thousands of qubits. The wiring system described herein is compatible with the measurement technology of a Josephson photomultiplier. To demonstrate, as shown in FIG. 3, part of the area in the qubit cell 300 and/or the corresponding cell 311 on the wiring substrate is used for the readout resonator 308 and a photomultiplier circuit 306. The readout resonator 308 and photomultiplier have sizes on the order of 0.01 mm² to 0.2 mm², which is considerably smaller than the typical qubit cell 300, with size 1 mm².

In another example, an integrated-circuit superconducting SQUID amplifier (e.g., electronics 110 at 3-4 K in the higher temperature section of FIG. 1), and a possible CMOS electronics for providing current and flux bias to the amplifier (e.g., electronics 110 at 3-4K), has low power dissipation (10's of μW) and small size about 1 mm², enabling a compact and modular design. These devices can be located on the interface substrate at its high-temperature end (e.g., top electronics 112 of top board 111, or on the wiring substrate in the high temperature section), or in another chip that is either bump-bonded to the interface substrate or on a printed circuit board or flex that is connected to the interface substrate.

In another example, as illustrated above in FIG. 1, various wiring connections exist that allow connection of electronics 110 on a board 109 near the wiring substrate 104 at (relatively) lower temperatures (e.g., 3-4 K) to connect to electronics 112 on a board 111 removed from the wiring substrate 104 at (relatively) higher temperatures (e.g., 270 K). To enable this thermal transition, a second wiring substrate is typically impractical, because the wiring would be made from a metal conductor such as Copper, and the micrometer-scale wires have a large series resistance (>1 kOhm). Instead, flex wiring is employed for these connects.

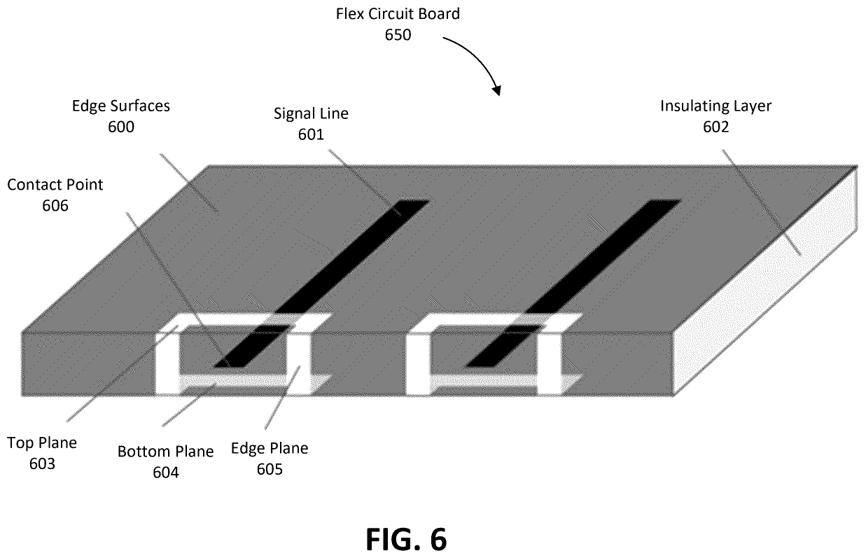

To demonstrate, FIG. 6 shows an isometric drawing of the microstrip flex circuit at the edge connection, in accordance with an embodiment of the invention. In the illustration, if referring to FIG. 1., the flex circuit 650 corresponds to some portion of the bottom flex circuit board (e.g., bottom flex circuit board 109) or some portion of the top flex circuit board (e.g., top flex circuit board 111). In context, the one or more flex circuits can be connected such that they form the bottom flex circuit board and the top flex circuit board illustrated in FIG. 1. To provide additional context, the bottom surface 606 of the flex circuit 650 is oriented in the-z direction of FIG. 1.

As illustrated, the top, bottom and edge surfaces 600 of the flex circuit board 650 are signal ground. These surfaces may be made from a Copper alloy. In this case, the surfaces 600 are drawn semi-transparently to show the microstrip signal line 601, which is separated by an insulating layer 602. The signal line 601 is connected to the Copper alloy at the edge 603 using edge plating. The signal line 601 is isolated from ground by etching the top 603 and bottom 604 ground planes, and the edge metal is removed 605 by laser cutting.

To provide an illustrative example, the flex circuit board 650 may include a stripline with outer ground planes 600 and an inner signal conductor 601 with width 200-500 um and thickness 10-30 um. These dimensions grant a much larger (>1000 times) cross-sectional area and enable a series resistance that is acceptably low for control signal transmission in quantum computation in large thermal gradient environments. As related above, the metal can be an alloy (e.g., a Copper alloy) such that the resulting resistivity is high and relatively independent of temperature, giving an acceptable thermal conductivity between the various temperature stages. Such an alloy can be fabricated using conventional flex manufacturing techniques, incorporating important features such as vias.

Additionally, in order to make dense connections from the wiring substrate (e.g., wiring substrate 104) to the flex circuit board 650, the spring contacts (e.g., spring contacts 108) from the wiring substrate to the contact point 606 of the signal line 601 on the flex circuit board. This configuration and structure enable a stack of flex substrates (e.g., as illustrated in FIG. 2 as boards 206) to densely connect en masse to the wiring substrate. This stack of flex substrates is then connected to higher temperature thermalization stages 111, such as 50-77 K, and then to 300 K. The flexibility of the flex wiring allows this stack to be spread out at higher temperatures, enabling components such as attenuators, microwave amplifiers, and control chips to be surface mounted on the flex 112 as in typical printed circuit boards. In some configurations, the stack of stripline transmission lines can be generated using 3D printing technology. The resulting stack may have the same cross-sectional profile as illustrated in FIG. 2. (e.g., boards 206).

Finally, the description turns towards devices and methods used to scale quantum computation.

The modular system described above enables scaling up the number of qubits, and that scaling depends on the exact dimensions of the various components. In an example configuration, the number of qubits in a single module may be around 20000 qubits using the illustrative dimensions and examples presented herein (e.g., FIGS. 1, 2, etc.). To scale to even larger size (e.g., a million qubits) more modules are combined together.

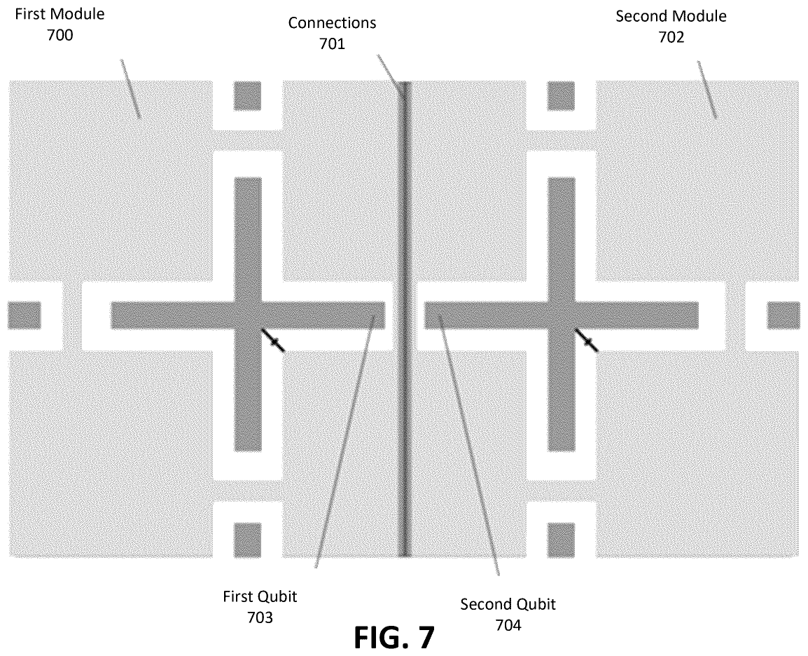

To illustrate, FIG. 7 shows an example tiling between two modules, in accordance with an example embodiment. The illustration includes a first qubit 703 on a first qubit substrate of a first module 700, and a second qubit 704 on a second qubit substrate of a second module 702. These modules 700, 702 are tiled together with qubits 703, 704 through capacitive coupling. By carefully aligning the qubit substrate to the mount, slightly inside the mount, mechanical connections (e.g., connections 701) will give a precise distance for this coupling capacitance.

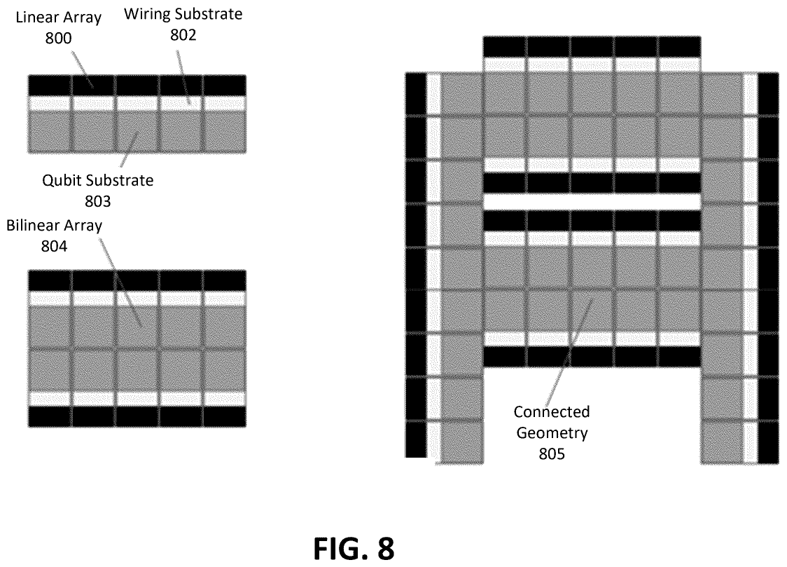

Tiling can be expanded to a greater degree. Indeed, FIG. 8 shows several examples for tiling modules, in accordance with an example embodiment. The illustrated example includes a linear array 800, a bi-linear array 804, and a connected geometry 805. The number of qubits spanning the edge of a module (e.g., 140 qubits) is much larger than the expected logical qubit size (e.g., 10 by 10 to 30 by 30) so that multiple logical operations can transmit down the tiles. The wiring and qubit substrates can be aligned precisely with the mechanical frame described previously in FIG. 7.

Within these examples, the flex wiring is connected to the wiring wafer and mount 801 (light grey), which is bump bonded to the qubit substrate 803 (dark grey). Here the qubit and wiring wafers are in the plane of the figure, and the flex wiring circuit boards extend out of the plane of the figure.

Reference in the specification to “one embodiment” or “an embodiment” means that a particular feature, structure, or characteristic described in connection with the embodiment is included in at least one embodiment of the system. The appearances of the phrase “in one embodiment” in various places in the specification are not necessarily all referring to the same embodiment.

Some portions of the detailed descriptions are presented in terms of algorithms or models and symbolic representations of operations on data bits within a computer memory. An algorithm is here, and generally, conceived to be steps leading to a desired result. The steps are those requiring physical transformations or manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Some of the operations described herein are performed by a computer physically mounted within a machine. This computer may be specially constructed for the required purposes, or it may comprise a general-purpose computer selectively activated or reconfigured by a computer program stored in the computer. Such a computer program may be stored in a computer-readable storage medium, such as, but is not limited to, any type of disk including floppy disks, optical disks, CD-ROMs, and magnetic-optical disks, read-only memories (ROMs), random access memories (RAMs), EPROMs, EEPROMs, magnetic or optical cards, or any type of non-transitory computer-readable storage medium suitable for storing electronic instructions.

The figures and the description above relate to various embodiments by way of illustration only. It should be noted that from the following discussion, alternative embodiments of the structures and methods disclosed herein will be readily recognized as viable alternatives that may be employed without departing from the principles of what is claimed.

One or more embodiments have been described above, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct physical or electrical contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present), and B is false (or not present), A is false (or not present), and B is true (or present), and both A and B is true (or present).

In addition, the use of the “a” or “an” are employed to describe elements and components of the embodiments herein. This is done merely for convenience and to give a general sense of the system. This description should be read to include one or at least one and the singular also includes the plural unless it is obvious that it is meant otherwise.

Upon reading this disclosure, those of skill in the art will appreciate still additional alternative structural and functional designs for a system and a process for implementing the functionality described herein. Thus, while particular embodiments and applications have been illustrated and described, it is to be understood that the disclosed embodiments are not limited to the precise construction and components disclosed herein. Various modifications, changes, and variations, which will be apparent to those, skilled in the art, may be made in the arrangement, operation, and details of the method and apparatus disclosed herein without departing from the spirit and scope defined in the appended claims.

What is claimed is:

1. A wiring system for a quantum computer comprising:
a qubit substrate comprising a plurality of qubits in a first thermal environment;
one or more control electronics in a second thermal environment warmer than the first thermal environment;
a wiring substrate comprising:
an intermediate section in a third thermal environment warmer than the first thermal environment and colder than the second thermal environment;
a plurality of transmission lines created using lithography processes, the plurality of transmission lines electrically connecting the plurality of qubits to the one or more control electronics; and
wherein the intermediate section is configured to dissipate thermal energy carried by the plurality of transmission lines into the intermediate section of the wiring substrate.

2. The wiring system of claim 1, the first thermal environment has a temperature of less than 50 mK, the second thermal environment has a temperature greater than 1K and less than 10 K, and the third thermal environment has a temperature greater than 250 mK and less than 750 mK.

3. The wiring system of claim 1, wherein the wiring substrate comprises a plurality of thinned sections, each thinned section structured for thermally isolating the thinned section from adjacent thermal environments.

4. The wiring system of claim 3, wherein the plurality of thinned sections comprises a first thinned section structured to thermally isolate the first thermal environment from the third thermal environment.

5. The wiring system of claim 3, wherein the plurality of thinned sections comprises a first thinned section structured to thermally isolate the second thermal environment from the third thermal environment.

6. The wiring system of claim 3, wherein a thinned section of the plurality of thinned sections comprises a window in the wiring substrate, and the window comprises a plurality of ribs providing structural support for the wiring substrate.

7. The wiring system of claim 1, wherein the intermediate section comprises a metal layer connecting the plurality of transmission lines to the intermediate section, the metal layer dissipating thermal energy from the plurality of transmission lines into a material of the intermediate section.

8. The wiring system of claim 1, wherein the intermediate section comprises a thermal stage configured for removing dissipated thermal energy from the wiring substrate.

9. The wiring system of claim 8, wherein the intermediate section is thermally coupled to the thermal stage by a metal layer and an epoxy.

10. The wiring system of claim 1, wherein the wiring substrate comprises:
an additional intermediate section in a fourth thermal environment warmer than the first thermal environment and third thermal environment and colder than the second thermal environment;
wherein the additional intermediate section is configured to dissipate at least some of the thermal energy carried by the plurality of transmission lines into the additional intermediate section of the wiring substrate.

11. The wiring system of claim 10, the first thermal environment has a temperature of less than 50 mK, the second thermal environment has a temperature greater than 1K and less than 10 K, the third thermal environment has a temperature greater than 100 mK and less than 400 mK, and the fourth thermal environment has a temperature greater than 600 mK and less than 900 mK.

12. The wiring system of claim 1, wherein the qubit substrate is bump bonded to the wiring substrate.

13. The wiring system of claim 12, wherein the bump bonds comprise Indium.

14. The wiring system of claim 1, wherein each transmission line of the plurality of transmission lines comprises a superconducting metal and an insulating material.

15. The wiring system of claim 14, wherein superconducting metal is niobium and the insulating material is silicon dioxide or silicon nitride.

16. The wiring system of claim 1, wherein the wiring substrate is formed from silicon or sapphire.

17. The wiring system of claim 1, wherein the qubit substrate is formed from silicon or sapphire.

18. The wiring system of claim 1, wherein a transmission line of the plurality of transmission lines comprises flex wiring, the flex wiring comprising a copper alloy in a stripline configuration.

19. The wiring system of claim 1, wherein the qubit substrate comprises at least 1000 qubits.

20. The wiring system of claim 1, wherein the wiring substrate comprising a plurality of transmission lines created using lithography processes comprises at least 1000 transmission lines.
